(19) United States
(12) Patent Application Publication
(10) Pub. No.: US 2019/0386160 A1
(43) Pub. Date: Dec. 19, 2019

(54) SOLAR CELL

(71) Applicant: PANASONIC CORPORATION, Osaka (JP)

(72) Inventors: Minato SENO, Osaka (JP); Shin NANBA, Osaka (JP)

(21) Appl. No.: 16/555,752

(22) Filed: Aug. 29, 2019

Related U.S. Application Data
(63) Continuation of application No. PCT/JP2018/008228, filed on Mar. 5, 2018.

(30) Foreign Application Priority Data
Mar. 31, 2017 (JP) 2017-069553

(51) Int. Cl. H01L 31/0224; H01L 31/074; H01L 31/0747; H01L 31/0288; H01L 31/0352

(52) U.S. Cl. CPC H01L 31/022441; H01L 31/074; H01L 31/03529; H01L 31/0288; H01L 31/0747

(57) ABSTRACT

A solar cell includes: a semiconductor substrate of a first conductivity type having a light receiving surface and a back surface; a first semiconductor layer of the first conductivity type disposed above the back surface; and a second semiconductor layer of a second conductivity type disposed above the back surface. The semiconductor substrate includes: a first impurity region including a first conductivity type impurity; and a third impurity region including the first conductivity type impurity and provided between the first impurity region and the first semiconductor layer. A concentration of the first conductivity type impurity in the third impurity region is higher than a concentration of the first conductivity type impurity in the first impurity region. A junction between the semiconductor substrate and the first semiconductor layer is a heterojunction.

### CROSS REFERENCE TO RELATED APPLICATIONS

This application is a U.S. continuation application of PCT International Patent Application Number PCT/JP2018/008228 filed on Mar. 5, 2018, claiming the benefit of priority of Japanese Patent Application Number 2017-069553 filed on Mar. 31, 2017, the entire contents of which are hereby incorporated by reference.

### BACKGROUND

### 1. Technical Field

The present disclosure relates to a solar cell.

### 2. Description of the Related Art

As a solar cell having a high photoelectric conversion characteristic, the so-called back contact solar cell of which an n-type semiconductor layer and a p-type semiconductor layer are formed on the back surface opposite to the light receiving surface of a semiconductor substrate is disclosed. For example, International Publication No. WO 2015/114903 discloses a back contact solar cell of which an n-type amorphous semiconductor layer and a p-type amorphous semiconductor layer are disposed on the back surface of a crystalline semiconductor substrate, and an intrinsic amorphous semiconductor layer is disposed between the crystalline semiconductor substrate and the n-type amorphous semiconductor layer and between the crystalline semiconductor substrate and the p-type amorphous semiconductor layer.

### SUMMARY

In a solar cell using a semiconductor substrate, carrier recombination at a surface of the semiconductor substrate greatly affects the photoelectric conversion characteristic. Therefore, a passivation film is disposed on the surface of the semiconductor substrate to reduce carrier recombination. However, although the passivation film is disposed, carrier recombination at the surface of the semiconductor substrate cannot be completely prevented. For this reason, there is a need for further reduction of carrier recombination.

A solar cell according to an aspect of the present disclosure includes: a semiconductor substrate of a first conductivity type having a light receiving surface and a back surface; a first semiconductor layer of the first conductivity type disposed above the back surface; a second semiconductor layer of a second conductivity type opposite to the first conductivity type disposed above the back surface; a first electrode electrically connected to the first semiconductor layer; and a second electrode electrically connected to the second semiconductor layer, wherein the semiconductor substrate includes: a first impurity region including a first conductivity type impurity; a third impurity region including the first conductivity type impurity and provided between the first impurity region and the first semiconductor layer; and a fourth impurity region including the first conductivity type impurity and provided between the first impurity region and the second semiconductor layer, a concentration of the first conductivity type impurity in the third impurity region is higher than a concentration of the first conductivity type impurity in the first impurity region, and a junction between the semiconductor substrate and the first semiconductor layer is a heterojunction.

According to an aspect of the present disclosure, it is possible to improve a photoelectric conversion characteristic of a solar cell.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a cross sectional view illustrating a structure of a solar cell according to an embodiment;

FIG. 2 is a plan view illustrating the back of the structure of the solar cell in FIG. 1 according to the embodiment;

FIG. 3 is a cross sectional view illustrating a structure of the solar cell according to another embodiment;

FIG. 4 is a cross sectional view illustrating a structure of the solar cell according to a variation;

FIG. 5 is a diagram schematically illustrating a manufacturing process of the solar cell;

FIG. 6 is a diagram schematically illustrating a manufacturing process of the solar cell;

FIG. 7 is a diagram schematically illustrating a manufacturing process of the solar cell;

FIG. 8 is a diagram schematically illustrating a manufacturing process of the solar cell;

FIG. 9 is a diagram schematically illustrating a manufacturing process of the solar cell; and

FIG. 10 is a diagram schematically illustrating a manufacturing process of the solar cell.

### DETAILED DESCRIPTION OF THE EMBODIMENTS

Hereinafter, embodiments will be described with reference to the drawings. Note that the embodiments below are mere examples, and the present disclosure is not limited to the embodiments below.

Note that the drawings are schematic diagrams, and do not necessarily provide strictly accurate illustration. For example, there may be a case in which, for example, a dimension ratio of a structural element is different from that of an actual element. The specific dimension ratio and the like are to be determined in consideration of the descriptions provided below. Throughout the drawings, the same sign is given to substantially the same element, and redundant description is omitted as appropriate.

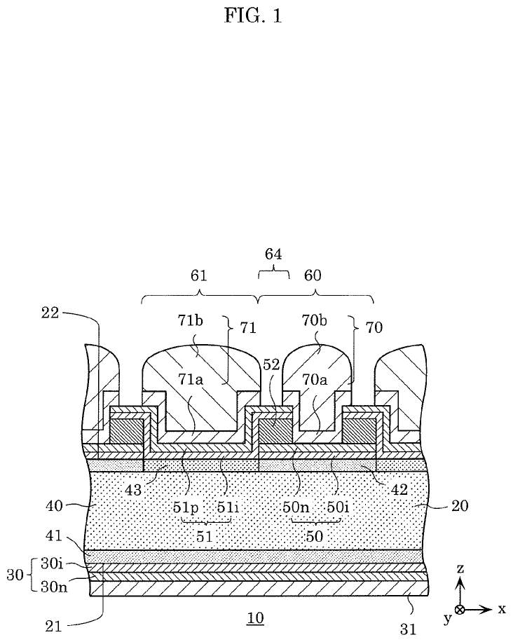

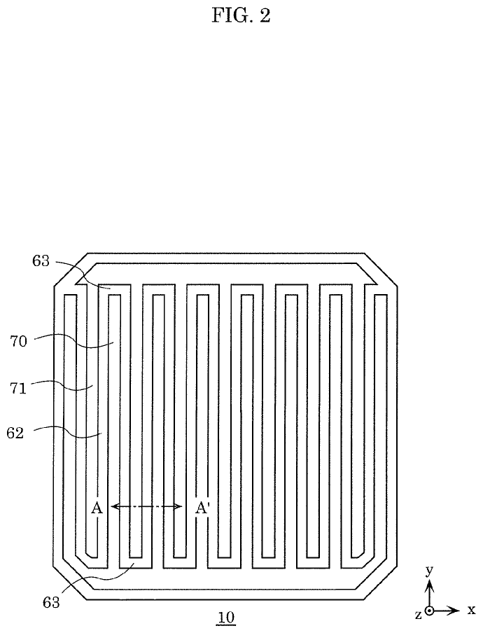

FIG. 1 is a cross sectional view illustrating solar cell 10 which is a back contact solar cell, and FIG. 2 is a plan view illustrating solar cell 10 which is viewed from the back. Note that FIG. 1 is a cross sectional view taken along line A-A′ in FIG. 2.

As illustrated in FIG. 1, solar cell 10 includes semiconductor substrate 20. Semiconductor substrate 20 has light receiving surface 21 and back surface 22. Light receiving surface 21 of semiconductor substrate 20 refers to a surface into which sunlight mainly enters, and back surface 22 refers to a surface opposite to light receiving surface 21. Semiconductor substrate 20 generates carriers by receiving light. Here, the carriers include an electron and a hole which are generated when semiconductor substrate 20 absorbs light.

Semiconductor substrate 20 is of a first conductivity type of either n-type or p-type. In order to improve the efficiency of utilizing incident light, light receiving surface 21 of semiconductor substrate 20 may have bumpy texture. In contrast, back surface 22 of semiconductor substrate 20 may or may not have bumpy texture. A bump in the bumpy texture ranges in size from 1 μm to 10 μm, for example.

As semiconductor substrate 20, a crystalline silicon substrate of either a monocrystalline silicon substrate or a polycrystalline silicon substrate can be used, for example. Note that, as semiconductor substrate 20, a substrate other than the crystalline silicon substrate can also be used. For example, a typical semiconductor substrate, such as a germanium (Ge) semiconductor substrate, a Iv-Iv compound semiconductor substrate that is represented by silicon carbide (SiC) and silicon germanium (SiGe), and a III-v compound semiconductor substrate that is represented by gallium arsenide (GaAs), gallium nitride (GaN), and indium phosphide (InP) can be used.

The embodiment describes an example of a case in which an n-type monocrystalline silicon substrate is used as semiconductor substrate 20 of a first conductivity type. In the example, the first conductivity type is n-type, and a second conductivity type which is opposite to the first conductivity type is p-type. The thickness of semiconductor substrate 20 is approximately 50 μm to 300 μm, for example. In addition, semiconductor substrate 20 includes, as a first conductivity type impurity that is doped with silicon, a dopant, such as phosphorus (P), arsenic (As), or antimony (Sb), for example. Substantially the entirety of semiconductor substrate 20 of the first conductivity type is formed of first impurity region 40 of the first conductivity type. The concentration of the first conductivity type impurity in first impurity region 40 is approximately 1×10¹⁴ cm⁻³ to 5×10¹⁶ cm⁻³, and preferably 5×10¹⁴ cm⁻³ to 5×10¹⁵ cm⁻³. Note that the first conductivity type may be p-type, and the second conductivity type may be n-type. In addition, semiconductor substrate 20 may be a polycrystalline silicon substrate.

As illustrated in FIG. 1, passivation layer 30 is disposed below the entirety of, or below substantially the entirety of light receiving surface 21 of semiconductor substrate 20. Passivation layer 30 includes a function that reduces carrier recombination at the joining interface between passivation layer 30 and semiconductor substrate 20. In the embodiment, an amorphous semiconductor layer is used as passivation layer 30. The amorphous semiconductor layer which is used as passivation layer 30 may be an amorphous silicon layer. According to the embodiment, passivation layer 30 has a stacked structure in which intrinsic amorphous silicon layer 30i and first conductivity type amorphous silicon layer 30n of the first conductivity type are stacked from light receiving surface 21 of semiconductor substrate 20 in the stated order. Intrinsic amorphous silicon layer 30i is disposed below and in contact with light receiving surface 21 of semiconductor substrate 20. First conductivity type amorphous silicon layer 30n is disposed below intrinsic amorphous silicon layer 30i. Semiconductor substrate 20 and passivation layer 30 form a heterojunction.

An “intrinsic semiconductor” in the present specification is not limited to a semiconductor completely intrinsic which does not include a conductivity-type impurity, but includes a semiconductor in which the inclusion of a conductivity-type impurity is intentionally avoided, and a semiconductor which includes a conductivity-type impurity that is being mixed during manufacturing processes and the like. Furthermore, in the case where a small amount of a conductivity-type impurity is intentionally or unintentionally added, the intrinsic semiconductor includes a semiconductor which is formed such that the concentration of the conductivity-type impurity of the semiconductor is below 5×10¹⁸ cm⁻³, for example. In addition, an “amorphous layer” in the present specification may include both an amorphous part and a crystalline part.

First conductivity type amorphous silicon layer 30n includes, as an impurity of the first conductivity type like semiconductor substrate 20, a dopant, such as phosphorus (P), arsenic (As), or antimony (Sb), for example. The dopant concentration of the first conductivity type impurity in first conductivity type amorphous silicon layer 30n is, for example, at least 1×10¹⁹ cm⁻³, and preferably at least 1×10²⁰ cm⁻³ and at most 5×10²¹ cm⁻³.

Passivation layer 30 is to be thick to an extent that carrier recombination at light receiving surface 21 of semiconductor substrate 20 can be sufficiently reduced, for example. On the other hand, passivation layer 30 is to be thin to an extent that incident light which passivation layer 30 absorbs can be suppressed as much as possible, for example. The thickness of passivation layer 30 is approximately 4 nm to 100 nm, for example. More specifically, the thickness of intrinsic amorphous silicon layer 30i is approximately 2 nm to 50 nm, for example. In addition, the thickness of first conductivity type amorphous silicon layer 30n is approximately 2 nm to 50 nm, for example.

In addition, as passivation layer 30, a layer other than the amorphous semiconductor layer can be used. For example, an insulating layer which includes a silicon compound containing at least one of oxygen (O) and nitrogen (N), or an aluminum compound containing at least one of oxygen (O) and nitrogen (N) can be used. The thickness of this insulating layer is approximately 1 nm to 100 nm, for example. A layer other than the amorphous semiconductor layer described above may be disposed between an amorphous semiconductor layer as passivation layer 30 and semiconductor substrate 20.

Below passivation layer 30, light-transmissive film 31 having a function of an antireflection film and a protective film is disposed in contact with passivation layer 30. As light-transmissive film 31, a light-transmissive insulating film or a light-transmissive conductive film can be used. The light-transmissive insulating film includes, for example, silicon oxide, silicon nitride, silicon oxynitride, aluminum oxide, aluminum nitride, or aluminum oxynitride. These compounds may contain hydrogen (H). The light-transmissive conductive film includes at least one of metallic oxides, such as indium oxide (In₂O₃), zinc oxide (ZnO), tin oxide (SnO₂), or titanium oxide (TiO₂). These metallic oxides may include an element, such as tin (Sn), zinc (Zn), tungsten (w), antimony (Sb), titanium (Ti), cerium (Ce), or gallium (Ga). The thickness of light-transmissive film 31 can be suitably determined according to the antireflective characteristic and the like. The thickness of light-transmissive film 31 is approximately 50 nm to 200 nm, for example. Light-transmissive film 31 may also have a function of a passivation film that reduces carrier recombination.

Above back surface 22 of semiconductor substrate 20, each of first semiconductor layer 50 of the first conductivity type and second semiconductor layer 51 of the second conductivity type opposite to the first conductivity type is disposed in the shape of a comb. A comb-teeth portion of first semiconductor layer 50 and a comb-teeth portion of second semiconductor layer 51 (a portion of first semiconductor layer 50 and a portion of second semiconductor 51 which extend in the y-axis direction, such as the portion of first semiconductor layer 50 and the portion of second semiconductor layer 51 illustrated in FIG. 1, for example) are alternately disposed, and are disposed such that the comb-teeth portion of first semiconductor layer 50 and the comb-teeth portion of second semiconductor layer 51 interdigitate with each other. In the embodiment, first conductive layer 50 is disposed above and in contact with back surface 22 of semiconductor substrate 20. In addition, region 64 in which second conductive layer 51 overlaps above first semiconductor layer 50 in the z-axis direction is provided. In region 64 in which first conductive layer 50 and second conductive layer 51 overlap each other, insulating layer 52 is disposed between first conductive layer 50 and second conductive layer 51. Insulating layer 52 includes a silicon compound or the like which contains at least one of oxygen (O) and nitrogen (N), for example. The thickness of insulating layer 52 is approximately 10 nm to 300 nm, for example.

First semiconductor layer 50 and second semiconductor layer 51 each also have a function of a passivation film, and reduce carrier recombination at the joining interface between semiconductor substrate 20 and first semiconductor layer 50 and between semiconductor substrate 20 and second semiconductor layer 51. As illustrated in FIG. 1, first region 60 is a region that corresponds to the joining surface between semiconductor substrate 20 and first semiconductor layer 50, and second region 61 is a region that corresponds to the joining surface between semiconductor substrate 20 and second semiconductor layer 51.

In the embodiment, a first amorphous semiconductor layer of the first conductivity type is used as first semiconductor layer 50 of the first conductivity type. The first amorphous semiconductor layer has a stacked structure in which intrinsic amorphous silicon layer 50i and first conductivity type amorphous silicon layer 50n of the first conductivity type are stacked from back surface 22 of semiconductor substrate 20 in the stated order. Intrinsic amorphous silicon layer 50i is disposed above and in contact with back surface 22 of semiconductor substrate 20 in first region 60. First conductivity type amorphous silicon layer 50n is disposed above intrinsic amorphous silicon layer 50i. First conductivity type amorphous silicon layer 50n includes, as an impurity of the first conductivity type like semiconductor substrate 20, a dopant, such as phosphorus (P), arsenic (As), or antimony (Sb), for example. The dopant concentration of the first conductivity type impurity in first conductivity type amorphous silicon layer 50n is, for example, at least 1×10¹⁰ cm⁻³, and preferably at least 1×10²⁰ cm⁻³ and at most 5×10²¹ cm⁻³. The thickness of intrinsic amorphous silicon layer 50i is approximately 2 nm to 50 nm, for example. The thickness of first conductivity type amorphous silicon layer 50n is approximately 2 nm to 50 nm, for example.

In the embodiment, a second amorphous semiconductor layer of the second conductivity type is used as second semiconductor layer 51 of the second conductivity type. The second amorphous semiconductor layer has a stacked structure in which intrinsic amorphous silicon layer 51i and second conductivity type amorphous silicon layer 51p of the second conductivity type are stacked from back surface 22 of semiconductor substrate 20 in the stated order. Intrinsic amorphous silicon layer 51i is disposed above and in contact with back surface 22 of semiconductor substrate 20 in second region 61. Second conductivity type amorphous silicon layer 51p is disposed above intrinsic amorphous silicon layer 51i. Second conductivity type amorphous silicon layer 51p includes, as a second conductivity type impurity, a dopant, such as boron (B). The dopant concentration of second conductivity type amorphous silicon layer 51p is, for example, at least 1×10¹⁰ cm⁻³, and preferably at least 1×10²⁰ cm⁻³ and at most 5×10²¹ cm⁻³. The thickness of intrinsic amorphous silicon layer 51i is approximately 2 nm to 50 nm, for example. The thickness of second conductivity type amorphous silicon layer 51p is approximately 2 nm to 50 nm, for example.

In the embodiment, semiconductor substrate 20 and first semiconductor layer 50 form a heterojunction, and semiconductor substrate 20 and second semiconductor layer 51 form a heterojunction which is a p-n junction. The adoption of these heterojunctions is for reducing carrier recombination at the joining interface between semiconductor substrate 20 and first semiconductor layer 50, and between semiconductor substrate 20 and second semiconductor layer 51, thereby improving the photoelectric conversion characteristic.

Note that, in order to improve the effect of reducing carrier recombination, each of the intrinsic amorphous silicon layers (30i, 50i, 51i), the first conductivity type amorphous silicon layers (30n, 50n), and the second conductivity type amorphous silicon layer (51p) may contain hydrogen (H). In addition, each of the intrinsic amorphous silicon layers (30i, 50i, 51i), the first conductivity type amorphous silicon layers (30n, 50n), and the second conductivity type amorphous silicon layer (51p) may contain oxygen (O), carbon (C), or germanium (Ge), in addition to hydrogen (H).

First semiconductor layer 50 and second semiconductor layer 51 are not limited to only the above descriptions. Each of first semiconductor layer 50 and second semiconductor layer 51 may have an insulating layer which includes a silicon compound containing at least one of oxygen (O) and nitrogen (N), or an aluminum compound and the like containing at least one of oxygen (O) and nitrogen (N) at the joining surface between first semiconductor layer 50 and semiconductor substrate 20, and between second semiconductor layer 51 and semiconductor substrate 20. In addition, each of first semiconductor layer 50 and second semiconductor layer 51 may have a stacked structure in which the insulating layer and a semiconductor layer of a conductivity type which contains at least one of monocrystalline silicon, polycrystalline silicon, and microcrystalline silicon are stacked from back surface 22 of semiconductor substrate 20 in the stated order. In the case of adopting this stacked structure, the insulating layer is to be thin to a degree that a tunnel current flows, for example. For instance, the thickness of the stacked structure is approximately 0.5 nm to 20 nm.

As illustrated in FIG. 1, first electrode 70 is disposed above first semiconductor layer 50, and is electrically connected to first semiconductor layer 50. On the other hand, second electrode 71 is disposed above second semiconductor layer 51, and is electrically connected to second semiconductor layer 51. First electrode 70 and second electrode 71 are electrically separated from each other. First electrode 70 collects majority carriers among carriers generated in semiconductor substrate 20, and second electrode 71 collects minority carriers among the carriers generated in semiconductor substrate 20. As illustrated in FIG. 2, first electrode 70 and second electrode 71 which correspond with first semiconductor layer 50 and second semiconductor layer 51, respectively, are disposed in the shape of a comb. A comb-teeth portion of first electrode 70 and a comb-teeth portion of second electrode 71 (a portion of first electrode 70 and a portion of second electrode 71 which extend in the y-axis direction, such as the portion of first electrode 70 and the portion of second electrode 71 illustrated in FIG. 1, for example) are disposed such that the comb-teeth portion of first electrode 70 and the comb-teeth portion of second electrode 71 interdigitate with each other. Accordingly, first electrode 70 and second electrode 71 are alternately disposed in the x-axis direction above back surface 22 of semiconductor substrate 20. Insulating region 62 is disposed between first electrode 70 and second electrode 71. Insulating region 62 is disposed such that insulating region 62 extends in the y-axis direction. Insulating region 62 makes a turn at turning region 63, and then extends in the opposite direction.

In the embodiment, first electrode 70 has a stacked structure in which first light-transmissive electrode layer 70a and first metal electrode layer 70b are stacked from above first semiconductor layer 50 in the stated order. First light-transmissive electrode layer 70a is disposed in contact with first semiconductor layer 50. First metal electrode layer 70b is disposed above first light-transmissive electrode layer 70a. In addition, second electrode 71 has a stacked structure in which second light-transmissive electrode layer 71a and second metal electrode layer 71b are stacked from above second semiconductor layer 51 in the stated order. Second light-transmissive electrode layer 71a is disposed in contact with second semiconductor layer 51. Second metal electrode layer 71b is disposed above second light-transmissive electrode layer 71a. Each of first light-transmissive electrode layer 70a and second light-transmissive electrode layer 71a includes at least one of metallic oxides, such as indium oxide (In₂O₃), zinc oxide (ZnO), tin oxide (SnO₂), or titanium oxide (TiO₂), for example. The metallic oxides may include an element, such as tin (Sn), zinc (Zn), tungsten (W), antimony (Sb), titanium (Ti), cerium (Ce), or gallium (Ga). Each of first metal electrode layer 70b and second metal electrode layer 71b may include metal, such as silver (Ag), copper (Cu), aluminum (Al), gold (Au), nickel (Ni), tin (Sn), or chromium (Cr), or an alloy including at least one kind of the metal, for example. Each of first metal electrode layer 70b and second metal electrode layer 71b may include a single layer or multiple layers.

As illustrated in FIG. 1, semiconductor substrate 20 includes, in the entirety from the surface of light receiving surface 21 to the vicinity of light receiving surface 21, second impurity region 41 of the first conductivity type whose concentration of the first conductivity type impurity is higher than the concentration of the first conductivity type impurity in impurity region 40. Second impurity region 41 is provided between first impurity region 40 of semiconductor substrate 20 and passivation layer 30. Second impurity region 41 is a region in which the concentration of first conductivity type impurity is at least 1×10¹⁷ cm⁻³, and the thickness is at most 5 μm, for example. Second impurity region 41 may have a region in which the concentration of first conductivity type impurity is at least 1×10¹⁷ cm⁻³ only in a range where the thickness is at most 5 μm from light receiving surface 21 of semiconductor substrate 20. Furthermore, second impurity region 41 may be a region in which the concentration of first conductivity type impurity is at least 5×10¹⁷ cm⁻³ and at most 5×10¹⁹ cm⁻³, and the thickness is at most 200 nm. In this case, second impurity region 41 may have a region in which the concentration of first conductivity type impurity is at least 5×10¹⁷ cm⁻³ and at most 5×10¹⁹ cm⁻³ only in a range where the thickness is at most 200 nm from light receiving surface 21 of semiconductor substrate 20.

In the embodiment, an electric field effect that is generated by providing second impurity region 41 whose concentration of the first conductivity type impurity is higher than the concentration of the first conductivity type impurity in first impurity region 40 from the surface of light receiving surface 21 of semiconductor substrate 20 to the vicinity of the surface of light receiving surface 21 of semiconductor substrate 20 reduces the density of the minority carriers generated in semiconductor substrate 20 at and in the vicinity of the joining interface between semiconductor substrate 20 and passivation layer 30. This reduces carrier recombination at the joining interface between semiconductor substrate 20 and passivation layer 30, and improves the photoelectric conversion characteristic.

Semiconductor substrate 20 includes, from the surface of back surface 22 of semiconductor substrate 20 to the vicinity of the surface of back surface 22, third impurity region 42 of the first conductivity type which includes the first conductivity type impurity, and fourth impurity region 43 of the first conductivity type which includes the first conductivity type impurity such that third impurity region 42 and fourth impurity region 43 are disposed next to each other. Third impurity region 42 is disposed to correspond with first semiconductor layer 50, and is disposed directly below first semiconductor layer 50 in a region in which first semiconductor layer 50 and semiconductor substrate 20 forms a heterojunction. Third impurity region 42 is provided between first impurity region 40 of semiconductor substrate 20 and first semiconductor layer 50. Fourth impurity region 43 is disposed to correspond with second semiconductor layer 51, and is disposed directly below second semiconductor layer 51 in a region in which second semiconductor layer 51 and semiconductor substrate 20 forms a heterojunction. Fourth impurity region 43 is provided between first impurity region 40 of semiconductor substrate 20 and second semiconductor layer 51. Third impurity region 42 may take up at least a portion below first semiconductor layer 50, and may take up the entirety of, or substantially the entirety of first semiconductor layer 50 below first semiconductor layer 50.

Fourth impurity region 43 may take up at least a portion below second semiconductor layer 51, and may take up the entirety of, or substantially the entirety of second semiconductor layer 51 below second semiconductor layer 51.

Here, the concentration of the first conductivity type impurity in third impurity region 42 is higher than the concentration of the first conductivity type impurity in first impurity region 40 and fourth impurity region 43. Accordingly, third impurity region 42 is selectively provided from the surface of back surface 22 of semiconductor substrate 20 to the vicinity of the surface of back surface 22 of semiconductor substrate 20 as a region having the concentration of the first conductivity type impurity higher than the surroundings. As such, on the back surface of a semiconductor substrate of the first conductivity type, the region having a high concentration of the first conductivity type impurity is selectively provided, corresponding to the heterojunction between the semiconductor substrate of the first conductivity type and a semiconductor layer of the first conductivity type. In the embodiment, third impurity region 42 is a region in which the concentration of first conductivity type impurity is at least 1×10¹⁷ cm⁻³, and the thickness is at most 5 μm, for example. Third impurity region 42 may have a region in which the concentration of first conductivity type impurity which is at least 1×10¹⁷ cm⁻³ in a range where the thickness is at most 5 μm from back surface 22 of semiconductor substrate 20. Furthermore, third impurity region 42 may be a region in which the concentration of first conductivity type impurity is at least 5×10¹⁷ cm⁻³ and at most 5×10¹⁹ cm⁻³, and the thickness is at most 200 nm, for example. Third impurity region 42 may have the concentration of first conductivity type impurity which is at least 5×10¹⁷ cm⁻³ and at most 5×10¹⁹ cm⁻³ in a range where the thickness is at most 200 nm from back surface 22 of semiconductor substrate 20.

In the embodiment, the concentration of an impurity in fourth impurity region 43 is lower than the concentration of the impurity in third impurity region 42. Note that due to the second conductivity type impurities which are intentionally or unintentionally added during the manufacturing processes, fourth impurity region 43 need not necessarily have the conductivity of the first conductivity type. Fourth impurity region 43 may be intrinsic or may be of the second conductivity type.

In the embodiment, first impurity region 40 refers to a region that includes the entirety of, or substantially the entirety of semiconductor substrate 20 excluding second impurity region 41, third impurity region 42, and fourth impurity region 43.

In the embodiment, an electric field effect that is generated by providing third impurity region 42 whose concentration of the first conductivity type impurity is higher than the concentration of the first conductivity type impurity in first impurity region 40 and fourth impurity region 43 below back surface 22 of semiconductor substrate 20 reduces the density of the minority carriers generated in semiconductor substrate 20 at and in the vicinity of the joining interface between semiconductor substrate 20 and first semiconductor layer 50. This reduces carrier recombination at the joining interface between semiconductor substrate 20 and first semiconductor layer 50, and improves the photoelectric conversion characteristic. When the concentration of first conductivity type impurity in third impurity region 42 is at least 1×10¹⁷ cm⁻³, it is possible to obtain the electric field effect that can markedly reduce carrier recombination at the joining interface between semiconductor substrate 20 and first semiconductor layer 50.

In addition, when the concentration of first conductivity type impurity is at most 5×10²⁰ cm⁻³, it is possible to prevent an increase in the number of defects generated in semiconductor substrate 20 as a result of providing third impurity region 42. Consequently, it is possible to further reduce carrier recombination at the joining interface between semiconductor substrate 20 and first semiconductor layer 50.

In addition, in the embodiment, since fourth impurity region 43 having the concentration of an impurity lower than the concentration of the impurity in third impurity region 42 is provided from the surface of back surface 22 of semiconductor substrate 20 to the vicinity of the surface of back surface 22 of semiconductor substrate 20, it is possible to prevent a crystal defect and the like from generating at and in the vicinity of the interface between semiconductor substrate 20 and second semiconductor layer 51 where semiconductor substrate 20 and second semiconductor layer 51 form a p-n junction, thereby reducing carrier recombination at the p-n junction interface between semiconductor substrate 20 and second semiconductor layer 51, and improving the photoelectric conversion characteristic.

As has been described in the embodiment, the provision of fourth impurity region 43 having the concentration of an impurity lower than the concentration of the impurity in third impurity region 42 on back surface 22-side of semiconductor substrate 20 makes it possible to prevent a crystal defect from generating at the p-n junction interface between semiconductor substrate 20 and second semiconductor layer 51. In the meanwhile, by selectively providing third impurity region 42 having a high concentration of first conductivity type impurity, carrier recombination at and in the vicinity of the joining interface between semiconductor substrate 20 and first semiconductor layer 50 can be reduced, and the photoelectric conversion characteristic can be improved.

Note that fourth impurity region 43 need not be provided, and fourth impurity region 43 may be a part of first impurity region 40.

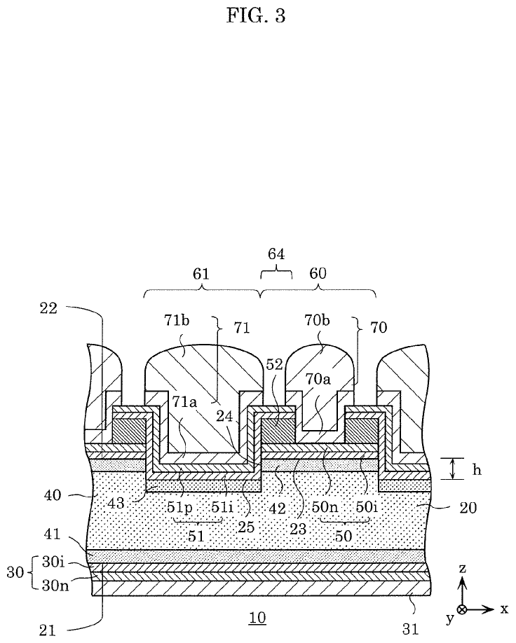

FIG. 3 is a cross sectional view illustrating a structure of solar cell 10 according to another embodiment. Back surface 22 of semiconductor substrate 20 has a bumpy structure which includes a plurality of grooves. The bumpy structure includes top faces 23 of raised portions, side faces 24 of the bumpy structure, and bottom faces 25 of recessed portions. Back surface 22 of semiconductor substrate 20 includes side face 24 of a protruding structure between top face 23 of a raised portion and bottom face 25 of a recessed portion which are next to each other. First semiconductor layer 50 is disposed above top faces 23 of raised portions of back surface 22 of semiconductor substrate 20. On the other hand, second semiconductor layer 51 is disposed beside side faces 24 of protrusion structures and above bottom faces 25 of the recessed portions of back surface 22 of semiconductor substrate 20. Third impurity region 42 is provided from top face 23 of a raised portion of back surface 22 of semiconductor substrate 20 to the inside of the raised portion. The thickness of third impurity region 42 may be greater than or less than height h from top face 23 of the raised portion to bottom face 25 of the recessed portion of the bumpy structure. Height h is, for example, a height of at most 10 μm, and preferably a height of at least 50 nm and at most 2 μm. Fourth impurity region 43 is provided below bottom face 25 of the recessed portion on back surface 22 of semiconductor substrate 20.

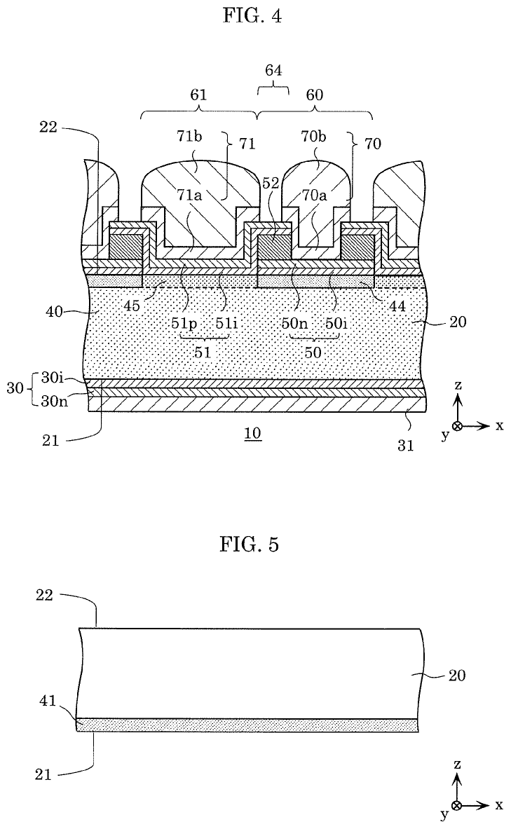

FIG. 4 is a cross sectional view illustrating a structure of solar cell 10 according to a variation. Differences between the embodiments described above and the variation are: (i) solar cell 10 according to the variation does not include second impurity region 41 and fourth impurity region 43; and (ii) instead of providing a third impurity region having a high concentration of the first conductivity type inside semiconductor substrate 20 like the embodiments described above, the third impurity region is provided above semiconductor substrate 20. The third impurity region is provided between semiconductor substrate 20 and first semiconductor layer 50. The same reference numerals are given to the same elements and corresponding elements, and thus descriptions of these elements will be omitted.

In the variation, the third impurity region is realized by first silicon oxide layer 44 which includes a first conductivity type impurity, for example. As the first conductivity type impurity, phosphorus (P), arsenic (As), antimony (Sb) or the like can be used, for example. The thickness of first silicon oxide layer 44 is, for example, at least 0.1 nm and at most 200 nm, and preferably at most 3 nm. In addition, the concentration of the first conductivity type impurity in first silicon oxide layer 44 is higher than the concentration of the first conductivity type impurity in first impurity region 40. The concentration of the first conductivity type impurity in first silicon oxide layer 44 is at least 1×10¹⁹ cm⁻³ and at most 5×10²⁰ cm⁻³, and the concentration of oxygen atom in first silicon oxide layer 44 is preferably at least 1×10²¹ cm⁻³ and at most 2×10²² cm⁻³. More preferably, the concentration of the first conductivity type impurity in first silicon oxide layer 44 is at least 5×10¹⁹ cm⁻³ and at most 1×10²⁰ cm⁻³, and the concentration of oxygen atom in first silicon oxide layer 44 is at least 2×10²¹ cm⁻³ and at most 5×10²¹ cm⁻³. Note that first silicon oxide layer 44 may be a crystalline layer or an amorphous layer.

As with the embodiments described above, it is possible to obtain an effect of reducing carrier recombination at the back of semiconductor substrate 20 by selectively disposing first silicon oxide layer 44 between semiconductor substrate 20 and first semiconductor layer 50.

In addition, when solar cell 10 according to the variation includes, between semiconductor substrate 20 and second semiconductor layer 51, second silicon oxide layer 45 including a first conductivity type impurity (a region indicated in dotted line in FIG. 4), the concentration of the first conductivity type impurity in second silicon oxide layer 45 may be lower than the concentration of the first conductivity type impurity in the first silicon oxide layer. Specifically, the thickness of the second silicon oxide layer is preferably at most 3 nm, the concentration of the first conductivity type impurity in the second silicon oxide layer is preferably at most 5×10¹⁹ cm⁻³, and the concentration of oxygen atom in the second silicon oxide layer is preferably at least 1×10²¹ cm⁻³ and at most 2×10²² cm⁻³. The disposition of the second silicon oxide layer having the concentration of the first conductivity type impurity lower than the concentration of the first conductivity type impurity in first silicon oxide layer 44 makes it possible to prevent a defect from generating at the p-n joining interface between semiconductor substrate 20 and second semiconductor layer 51. In the meanwhile, the disposition of first silicon oxide layer 44 having a high concentration of the first conductivity type impurity makes it possible to reduce carrier recombination at and in the vicinity of the joining interface between semiconductor substrate 20 and first semiconductor layer 50, and to improve the photoelectric conversion characteristic.

Note that first silicon oxide layer 44 is an example of the third impurity region, and second silicon oxide layer 45 is an example of the fourth impurity region. In addition, solar cell 10 according to the variation may include second impurity region 41 like the embodiments described above.

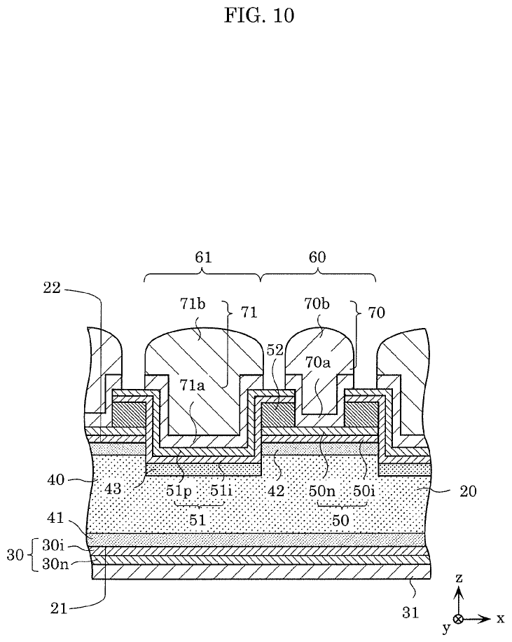

Hereinafter, a method for manufacturing the solar cell according to the embodiment will be described with reference to the drawings. FIG. 5 through FIG. 10 are drawings schematically illustrating manufacturing processes of the solar cell according to the embodiment.

Firstly, as illustrated in FIG. 5, a crystalline silicon substrate of the first conductivity type is prepared as semiconductor substrate 20. Second impurity region 41 that includes a first conductivity type impurity is formed on light receiving surface 21-side of semiconductor substrate 20. Second impurity region 41 can be formed using, for example, a thermal diffusion method, a plasma doping method, an epitaxial growth method, an ion implantation method, or the like. According to the embodiment, phosphorus (P), arsenic (As), antimony (Sb), or the like can be used as the first conductivity type impurity, for example.

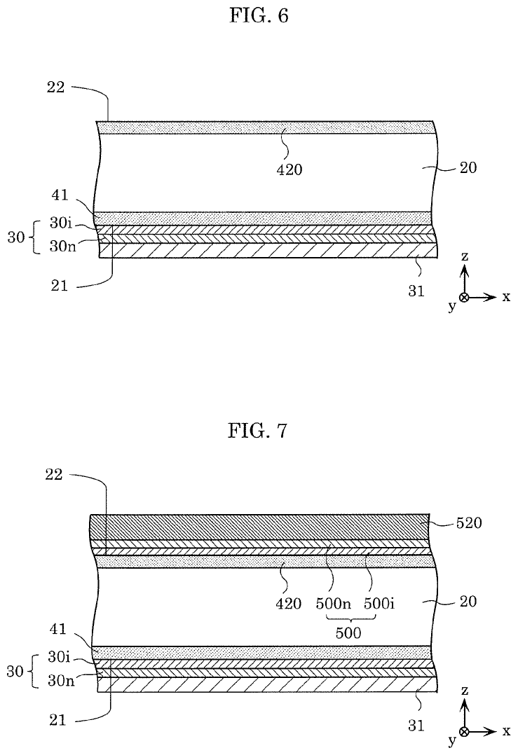

Next, below second impurity region 41 of semiconductor substrate 20, passivation layer 30 and light-transmissive film 31 are formed from light receiving surface 21 in the stated order as illustrated in FIG. 6. As passivation layer 30, intrinsic amorphous silicon layer 30i and first conductivity type amorphous silicon layer 30n of the first conductivity type are formed from light receiving surface 21 in the stated order. Passivation layer 30 can be formed using, for example, a chemical vapor deposition (CVD) method, such as a plasma CVD method. Intrinsic amorphous silicon layer 30i can be formed using source gas which is silane (SiH₄) diluted with hydrogen (H₂). First conductivity type amorphous silicon layer 30n can be formed using source gas which is silane (SiH₄) to which phosphine (PH₃) is added and then diluted with hydrogen (H₂). Light-transmissive film 31 can be formed using, for example, a sputtering method, a vacuum evaporation method, a CVD method, or the like.

Next, high impurity region 420 which includes the first conductivity type impurity is formed below the entirety of, or below substantially the entirety of back surface 22 of semiconductor substrate 20. According to the embodiment, phosphorus (P), arsenic (As), antimony (Sb), or the like can be used as the first conductivity type impurity, for example. High impurity region 420 can be formed using, for example, a thermal diffusion method, a plasma doping method, an epitaxial growth method, an ion implantation method, or the like. In the thermal diffusion method, the use of phosphorus oxychloride (POCl₃) gas enables phosphorus (P) which is the first conductivity type impurity to be suitably added to back surface 22 while the generation of a defect at back surface 22 is prevented. In the plasma doping method, source gas which is phosphine (PH₃) diluted with hydrogen (H₂) can be used. This makes it possible to reduce the manufacturing cost of the manufacturing method for forming high impurity region 420 and first semiconductor layer 50 in the same device using a vapor deposition method, such as the plasma CVD method. Compared with the thermal diffusion method, the epitaxial growth method steeply increases the concentration of the first conductivity type impurity in high impurity region 420 at the joining interface between semiconductor substrate 20 and first semiconductor layer 50, and thus the concentration of the first conductivity type impurity in high impurity region 420 as a whole can be readily evened out. In the case of using the ion implantation method, high-temperature annealing may be used together with the ion implantation method in order to reduce a defect generated during the ion implantation. In addition, in the case of using the thermal diffusion method, the plasma doping method, and the ion implantation method, a concentration gradient in which the concentration of the first conductivity type impurity is highest at back surface 22 of semiconductor 20 and gradually becomes lower as the distance from back surface 22 increases is formed.

Next, as first conductivity type semiconductor substrate 500 which is of first conductivity type, intrinsic amorphous silicon layer 500i and first conductivity type amorphous silicon layer 500n are formed above the entirety of, or above substantially the entirety of high impurity region 420 of semiconductor substrate 20 from back surface 22 in the stated order, as illustrated in FIG. 7. First conductivity type semiconductor layer 500 can be formed using, for example, the CVD method, such as the plasma CVD method. Intrinsic amorphous silicon layer 500i can be formed using source gas which is silane (SiH₄) diluted with hydrogen (H₂). First conductivity type amorphous silicon layer 500n can be formed using source gas which is silane (SiH₄) to which phosphine (PH₃) is added and then diluted with hydrogen (H₂). Next, insulating layer 520 is formed above first conductivity type semiconductor layer 500. For example, insulating layer 520 can be formed using the CVD method, the sputtering method, or the like.

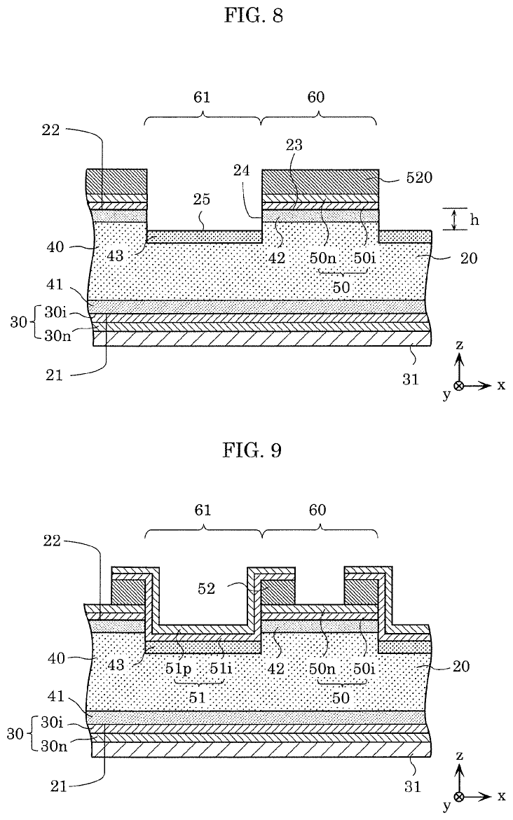

Next, first conductivity type semiconductor layer 500 and insulating layer 520 above back surface 22 of semiconductor substrate 20 in second region 61 where second semiconductor layer 51 of the second conductivity type is formed are removed so that back surface 22 of semiconductor 20 in second region 61 is exposed as illustrated in FIG. 8. In this process, the entirety of or a portion of high impurity region 420 of semiconductor substrate 20 in second region 61 is also removed. Consequently, first semiconductor layer 50 which has a stacked structure that includes intrinsic amorphous silicon layer 50i and first conductivity type amorphous silicon layer 50n, and third impurity region 42 are formed. When the thermal diffusion method or the plasma doping method is used for forming high impurity region 420, fourth impurity region 43 can be also formed due to the concentration gradient that occurs in high impurity region 420. A chemical etching method that uses resist pattern as a mask can selectively remove a region in each of first conductivity type semiconductor layer 500, insulating layer 520, and semiconductor substrate 20 which corresponds to second region 61. Insulating layer 520 can be etched and then removed using an acid etching solution such as a hydrofluoric acid aqueous solution. First conductivity type semiconductor layer 500 and semiconductor substrate 20 can be etched and then removed using an alkaline etching solution. After the etching and the removing, the resist pattern which becomes unnecessary can be peeled off and removed using tetra methyl ammonium hydroxide (TMAH), for example.

In addition, in this removing process, the surface of semiconductor substrate 20 in second region 61 may be removed so as to form grooves in back surface 22 of semiconductor substrate 20, as illustrated in FIG. 8. The grooves form the bumpy structure which includes top faces 23 of raised portions, side faces 24 of the bumpy structure, and bottom faces 25 of recessed portions on back surface 22 of semiconductor substrate 20. Height h from top face 23 of a raised portion to bottom face 25 of a recessed portion of the bumpy structure can be suitably set according to (i) the concentration gradient of the concentration of first conductivity type impurity in high impurity region 420 from back surface 22 of semiconductor substrate 20, (ii) the thickness of fourth impurity region 43 to be formed and the concentration of first conductivity type impurity in fourth impurity region 43 to be formed, and (iii) the manufacturing cost and the like relating to etching methods. Height h from top face 23 of a raised portion to bottom face 25 of a recessed portion of the bumpy structure is, for example, at most 10 μm, and preferably at least 50 nm and at most 2 μm. The adoption of a manufacturing method which provides the bumpy structure can prevent an increase in the manufacturing cost while suitably producing an effect of improving the photoelectric conversion characteristic as a result of providing third impurity region 42 in semiconductor substrate 20 in first region 60.

Next, second conductivity type semiconductor layer which is of the second conductivity type is formed above the entirety of back surface 22 so as to cover the exposed surface of semiconductor substrate 20 in second region 61 and insulating layer 520 in first region 60. As the second conductivity type semiconductor layer, an intrinsic amorphous silicon layer and a second conductivity type amorphous silicon layer which includes the second conductivity type are formed in the stated order. The second conductivity type semiconductor layer can be formed using, for example, the CVD method, such as the plasma CVD method. The intrinsic amorphous silicon layer can be formed using source gas which is silane (SiH₄) diluted with hydrogen (H₂). The second conductivity type amorphous silicon layer can be formed using source gas which is silane (SiH₄) to which diborane (B₂H₆) is added and then diluted with hydrogen (H₂).

Next, in order to provide, in a later process, first electrode 70 that electrically connects with first semiconductor layer 50, the second conductivity type semiconductor layer and insulating layer 520 above first semiconductor layer 50 are removed. A chemical etching method that uses resist pattern as a mask can remove the second conductivity type semiconductor layer and insulating layer 520. The second conductivity type semiconductor layer can be etched and removed using an alkaline etching solution. Second semiconductor layer 51 is formed as a result of the etching and the removing of a portion of the second conductivity type semiconductor layer. Specifically, intrinsic amorphous silicon layer 51i is formed as a result of the etching and the removing of a portion of the intrinsic amorphous silicon layer formed above the entirety of back surface 22. In addition, second conductivity type amorphous silicon layer 51p is formed as a result of the etching and the removing of a portion of the second conductivity type amorphous silicon layer formed above the entirety of back surface 22.

Insulating layer 520 can be etched and removed using an acid etching solution, such as a hydrofluoric acid aqueous solution. After the etching and the removing, the resist pattern which becomes unnecessary can be peeled off and removed using TMAH, for example. Consequently, as illustrated in FIG. 9, the surface of first semiconductor layer 50 is exposed, and second semiconductor layer 51 is formed above back surface 22 of semiconductor substrate 20 in second region 61.

Finally, as first electrode 70, first light-transmissive electrode layer 70a and first metal electrode layer 70b are formed above first semiconductor layer 50 in the stated order. In addition, as second electrode 71, second light-transmissive electrode layer 71a and second metal electrode layer 71b are formed above second semiconductor layer 51 in the stated order. Each of first light-transmissive electrode layer 70a and second light-transmissive electrode layer 71a can be formed using the sputtering method, the vacuum evaporation method, or the CVD method, for example. On the other hand, each of first metal electrode layer 70b and second metal electrode layer 71b can be formed using an electrolytic plating method, a printing method, or the vacuum evaporation method.

The method of forming third impurity region 42 is not limited to only the above descriptions. As has been described above in the manufacturing method, third impurity region 42 may be formed: (i) as a result of the etching and the removing of high impurity region 420 formed above semiconductor substrate 20 in second region 61 after high impurity region 420 is formed below the entirety of, or below substantially the entirety of back surface 22 of semiconductor substrate 20; or (ii) using, for example, a mask, by adding the first conductivity type impurity only to back surface 20 of semiconductor substrate 20 in first region 60. Furthermore, before forming passivation layer 30 and first semiconductor layer 50, the first conductivity type impurity can be added to the entirety of, or substantially the entirety of the surface of each light receiving surface 21 and back surface 22 of semiconductor substrate 20 using the thermal diffusion method to simultaneously form second impurity region 41 and high impurity region 420. Then, in a later process, the entirety of or a portion of high impurity region 420 of semiconductor substrate 20 in second region 61 may be removed.

In the method of manufacturing the solar cell according to the variation, a silicon oxide layer which includes the first conductivity type impurity is to be formed in the entirety of, or in substantially the entirety of a region below back surface 22 of semiconductor substrate 20, instead of forming high impurity region 420 in the process of forming high impurity region 420. The silicon oxide layer which includes the first conductivity type impurity can be formed using, for example, the CVD method, such as the plasma CVD method. The silicon oxide layer which includes the first conductivity type impurity can be formed using source gas mixed with gas containing silicon, such as silane (SiH₄), gas containing the first conductivity type impurity, such as phosphine (PH₃), and gas containing oxygen, such as O₂, H₂O, or CO₂. As with the manufacturing method described above, first silicon oxide layer 44, and second silicon oxide layer 45 as necessary, can be only formed below back surface 22 of semiconductor layer 20 in first region 60 as a result of the etching and the removing of the entirety of or a portion of the silicon oxide layer which includes the first conductivity type impurity above semiconductor substrate 20 in second region 61 after the silicon oxide layer which includes the first conductivity type impurity is formed. The silicon oxide layer which includes the first conductivity type impurity can be etched and removed using an alkaline etching solution.

Note that the order of processes in the method of manufacturing the solar cell described above is an example, and thus the order of the processes are not limited to the example. In addition, some of the processes need not be performed.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell, comprising:
a semiconductor substrate of a first conductivity type having a light receiving surface and a back surface;
a first semiconductor layer of the first conductivity type disposed above the back surface;
a second semiconductor layer of a second conductivity type opposite to the first conductivity type disposed above the back surface;
a first electrode electrically connected to the first semiconductor layer; and
a second electrode electrically connected to the second semiconductor layer, wherein
the semiconductor substrate includes:
a first impurity region including a first conductivity type impurity; and
a third impurity region including the first conductivity type impurity and provided between the first impurity region and the first semiconductor layer,
a concentration of the first conductivity type impurity in the third impurity region is higher than a concentration of the first conductivity type impurity in the first impurity region, and
a junction between the semiconductor substrate and the first semiconductor layer is a heterojunction.

2. The solar cell according to claim 1, further comprising:
a fourth impurity region including the first conductivity type impurity and provided between the first impurity region and the second semiconductor layer, wherein
a concentration of the first conductivity type impurity in the fourth impurity region is lower than a concentration of the first conductivity type impurity in the third impurity region.

3. The solar cell according to claim 1, wherein
the semiconductor substrate has a bumpy structure on the back surface, the bumpy structure including a groove,
the first semiconductor layer is disposed above a top face of a raised portion of the bumpy structure, and
the second semiconductor layer is disposed above a bottom face of a recessed portion of the bumpy structure.

4. The solar cell according to claim 1, further comprising:
a passivation layer disposed below the light receiving surface, wherein
the semiconductor substrate includes:
a second impurity region including the first conductivity type impurity and provided between the first impurity region and the passivation layer,
a concentration of the first conductivity type impurity in the second impurity region is higher than a concentration of the first conductivity type impurity in the first impurity region, and
a junction between the semiconductor substrate and the passivation layer is a heterojunction.

5. The solar cell according to claim 1, wherein
the semiconductor substrate is a crystalline semiconductor substrate, and
the first semiconductor layer is an amorphous semiconductor layer.

6. The solar cell according to claim 1, wherein
the semiconductor substrate is a crystalline silicon substrate, and
the first semiconductor layer has a stacked structure that includes an intrinsic amorphous silicon layer and a first conductivity type amorphous silicon layer.

7. The solar cell according to claim 1, wherein
the third impurity region is provided inside the semiconductor substrate.

8. The solar cell according to claim 1, wherein
the third impurity region is provided above the semiconductor substrate.
